(19) United States
(12) Patent Application Publication
(10) Pub. No.: US 2024/0147644 A1
(43) Pub. Date: May 2, 2024

(54) Hinges for Folding Devices

(71) Applicant: Apple Inc., Cupertino, CA (US)

(72) Inventors: Scott J Krahn, Cupertino, CA (US); Robert Y Cao, San Francisco, CA (US); Lei Wang, Hangzhou (CN); Ke Ye, Hangzhou (CN); Zhouying Chen, Hangzhou (CN)

(21) Appl. No.: 18/482,345

(22) Filed: Oct. 6, 2023

Related U.S. Application Data
(60) Provisional application No. 63/421,660, filed on Nov. 2, 2022.

(51) Int. Cl. H05K 5/02; F16C 11/04

(52) U.S. Cl. CPC H05K 5/0226; F16C 11/04

(57) ABSTRACT

A foldable display device may have housing portions coupled by a hinge. A flexible display may overlap the hinge. The hinge may have portions that rotate relative to each other about rotational axes that lie above the hinge to help reduce stress to the display. The hinge may have gear plates with interlocked teeth that synchronize rotational movement between left and right halves of the hinge. The hinge may also have asymmetric friction clips that impose different amounts of rotational friction to the hinge depending on the direction of rotation of the hinge.

This application claims the benefit of provisional patent application No. 63/421,660, filed Nov. 2, 2022, which is hereby incorporated by reference herein in its entirety.

### FIELD

This relates generally to electronic devices, and, more particularly, to electronic devices with hinges.

### BACKGROUND

Electronic devices often have displays. Portability may be a concern for some devices, which tends to limit available real estate for displays.

### SUMMARY

A foldable display device may have housing portions coupled by a hinge. A flexible display may overlap the hinge. The foldable device may be moved between folded and unfolded positions using the hinge.

The hinge may have portions that rotate relative to each other about axes that lie above the hinge to help reduce stress to the display. The hinge may also have synchronization gear plates. The gear plates may have interlocked teeth that synchronize rotational movement between left and right halves of the hinge.

Friction clips may be included in the hinge. The friction clips may be asymmetric friction clips that impose different amounts of rotational friction to portions of the hinge depending on the direction of rotation of the hinge portions.

### BRIEF DESCRIPTION OF THE DRAWINGS

FIG. 1 is a perspective view of an illustrative electronic device with a display in accordance with an embodiment.

FIG. 2 is a side view of a portion of an illustrative electronic device having a hinge with links in accordance with an embodiment.

FIGS. 3 and 4 are perspective views of portions of an illustrative hinge in accordance with an embodiment.

FIG. 5 is a side view of a pair of geared synchronization plates with interlocking teeth in accordance with an embodiment.

FIG. 6 is a side view of an illustrative friction transfer arm in accordance with an embodiment.

FIG. 7 is a side view of half of an illustrative hinge in accordance with an embodiment.

FIG. 8 is a perspective view of an illustrative hinge in accordance with an embodiment.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode display or a display formed from an array of micro-light-emitting diodes (e.g., light-emitting diodes formed from crystalline semiconductor dies).

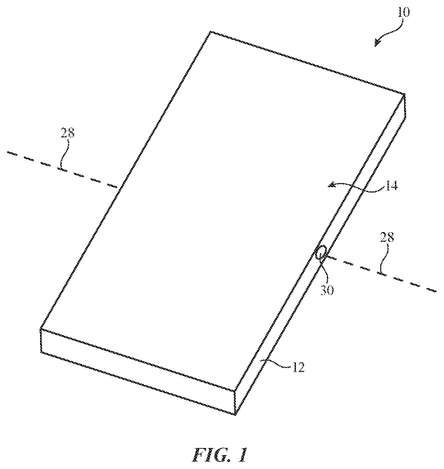

A schematic diagram of an illustrative electronic device having a display is shown in FIG. 1. Device 10 may be a cellular telephone, a computer, or other portable electronic device. Configurations in which device 10 is a foldable device such as a foldable cellular telephone or foldable computer may sometimes be described herein as example.

As shown in FIG. 1, device 10 may include a display such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display or microLED display are sometimes described herein as an example.

Display 14 may have an array of pixels configured to display images for a user. The pixels may be formed as part of a display panel that is bendable. This allows device 10 to be folded and unfolded about a bend axis such as bend axis 28. For example, a flexible (bendable) display in device 10 may be folded so that device 10 may be placed in a compact shape for storage and may be unfolded when it is desired to view images on the display. Display 14 may cover some or all of the front face of device 10. Touch sensor circuitry such as two-dimensional capacitive touch sensor circuitry may be incorporated into display 14.

Display 14 may be mounted in housing 12. Housing 12 may form front and rear housing walls, sidewall structures, and/or internal supporting structures (e.g., a frame, an optional midplate member, etc.) for device 10. Glass structures, transparent polymer structures, and/or other transparent structures that cover display 14 and other portions of device 10 may provide structural support for device 10 and may sometimes be referred to as housing structures. For example, a transparent housing portion such as a glass or polymer housing structure that covers and protects a pixel array in display 14 may serve as a display cover layer for the pixel array while also serving as a housing wall on the front face of device 10. In configurations in which a display cover layer is formed from glass, the display cover layer may sometime be referred to as a display cover glass or display cover glass layer. The portions of housing 12 on the sidewalls and rear wall of device 10 may be formed from glass or other transparent structures and/or opaque structures. Sidewalls and rear wall structures may be formed as extensions to the front portion of housing 12 (e.g., as integral portions of the display cover layer) and/or may include separate housing wall structures.

Housing 12 may have flexible structures (e.g., bendable housing wall structures) and/or hinge structures such as hinge 30. Hinge 30 may fold about device bend axis 28. Hinge 30 and/or flexible housing structures that overlap bend axis 28 may allow housing 12 to bend about bend axis 28. For example, housing 12 may have a first portion on one side of bend axis 28 and a second portion on an opposing side of bend axis 28 and these two housing portions may be coupled by hinge 30 for rotational motion about axis 28.

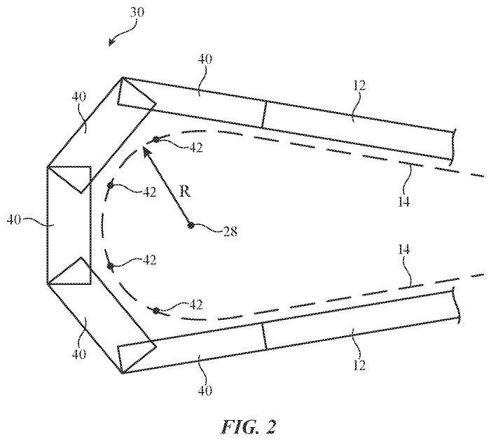

As housing 12 is bent about bend axis 28, the flexibility of display 14 allows display 14 to bend about axis 28. In an illustrative configuration, housing 12 and display 14 may bend by 180°. This allows display 14 to be folded back on itself (with first and second outwardly-facing portions of display 14 facing each other). The ability to place device 10 in a folded configuration in this way may help make device 10 compact so that device 10 can be stored efficiently. When it is desired to view images on display 14, device 10 may be unfolded about axis 28 to place device 10 in the unfolded configuration of FIG. 2. This allows display 14 to lie flat and allows a user to view flat images on display 14. The ability to fold display 14 onto itself allows device 10 to exhibit an inwardly folding behavior. If desired device 10 may be folded outwardly and/or inwardly. Inward-folding arrangements are described herein as an example.

Hinge 30 may have a multisegment design. As shown in FIG. 2, for example, hinge 30 may have multiple interconnected portions such as hinge links 40. Links 40 may be coupled to each other for rotational motion and may extend in a linked series between first and second portions of housing 12 (e.g., the halves of housing 12 of FIG. 1 that rotate with respect to each other). Each pair of adjacent hinge links may be restricted in its amount of overall rotation. For example, links 40 may be configured so that no two adjacent links 40 are allowed to rotate more than a maximum rotation angle RA with respect to each other where RA has a value of less than 180°, less than 90°, less than 45°, less than 25°, 5-50°, or other suitable amount. With this arrangement, links 40 collectively allow hinge 30 to rotate by a desired amount (e.g., 180°) without creating an excessively small bend radius for display 14 about bend axis 28.

With an illustrative arrangement, hinge portions such as links 40 may have crescent shaped slots with mating pins and/or other structures such as mating crescent-shaped grooves and ridges that place the axes of rotations of the housing portions outside of the layer of links themselves (e.g., outside of the structures forming hinge 30). As shown in FIG. 2, for example, each link in a pair of adjacent links may rotate with respect to the other about a rotational axis 42 (sometimes referred to as a virtual pivot point) that is located outside of hinge 30 towards hinge bend axis 28. Although each adjacent set of links can only rotate by a limited amount in this type of arrangement, the overall amount of bending of display 14 may be 180° or more by using multiple links 40 in hinge 30, thereby allowing display 14 to fold back on itself. To help minimize bending stress on display 14, display 14 may be placed in alignment with axes 42. The bend radius R of display 14 when device 10 is folded shut may be sufficient to prevent excess stress to display 14. For example, R may have a value of 5 mm, at least 1 mm, at least 3 mm, less than 10 mm, less than 6 mm, 2-7 mm, or other suitable value).

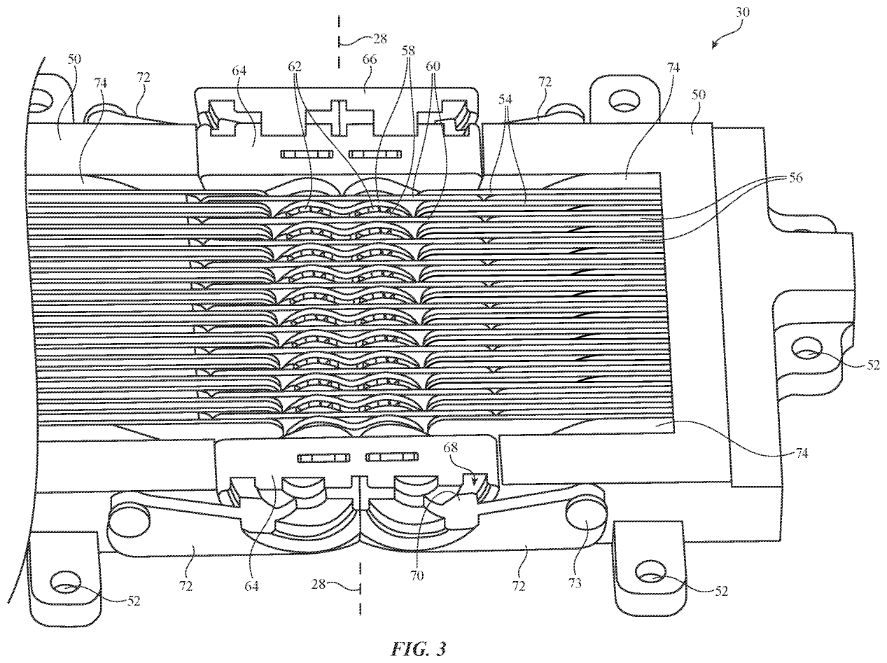

FIG. 3 is a perspective view of a portion of an illustrative hinge for device 10. As shown in FIG. 3, hinge 30 may have left and right mounting blocks 50, with screw holes 52. Blocks 50 may be mounted to respective left and right halves of housing 12 using screws that are received in screw holes 52.

Each of mounting blocks 50 may be rigidly attached to a set of associated interleaved support plates such as spacer support plates 54 and outer support plates 56. During folding and unfolding of hinge 30 about axis 28, plates 54 and 56 on the left side of hinge 30 rotate in unison with the left mounting block 50, whereas plates 54 and 56 on the right side of hinge 30 rotate in unison with the right mounting block 50.

Inner support plates 60, which are aligned with respective outer support plates 56 on the left and right sides of hinge 30, receive left and right shafts that extend parallel to axis 28 and remain horizontal (in the orientation of FIG. 3) as the left and right mounting plates are folded upwards to close device 10.

To provide satisfactory hinge friction, hinge 30 may have friction clips 58 that bear against the left and right shafts passing through the center of hinge 30 parallel to axis 28. The left and right halves of hinge 30 are also provided with respective mating left and right gear plates 62 (sometimes referred to as synchronization gear plates or rotational synchronization gear plates). Each of gear plates 62 is sandwiched between a pair of respective friction clips 58 and may have a thickness of less than 6 mm, less than 4 mm, less than 2 mm, or less than 1 mm (as examples). The mating gear plates 62 of hinge 30 have interlocking teeth and synchronize rotational motion of the right and left halves of hinge 30.

The hinge arrangement of FIG. 3 therefore has (on each side) multiple sets of hinge structures overlapping axis 28. Each set includes (in order): 1) a first friction clip 58 aligned with a first spacer support plate 54, 2) an inner support plate 60 aligned with a corresponding outer support plate 56, 3) a second friction clip 58 aligned with a second spacer support plate 54, and 4) a gear plate 62. The thickness of these plates may be, as an example, less than 5 mm less than 4 mm, less than 3 mm, less than 2 mm, or less than 1 mm. The sets of hinge structures are stacked along axis 28. In the example of FIG. 3, there are ten sets of stacked hinge structures, but fewer or more stacked hinge structures may be used, if desired.

At each of the two opposing ends of hinge 30 (towards the top and bottom of the page in the orientation of FIG. 3), hinge 30 has a corresponding crescent block 64. Crescent blocks 64 may be covered with caps such as cap 66. Only one cap 66 is shown in FIG. 3 to avoid blocking the details of the lower crescent block from view.

As shown in FIG. 3, each crescent block 64 has crescent-shaped grooves 68. These receive corresponding crescent-shaped ridges 70 on the inner ends of respective crescent links 72. The outer end of each link 72 is rotatably coupled to a respective one of blocks 50 using a respective pin 73. During rotation of hinge 30, ridges 70 slide within grooves 68 so that each of links 72 rotates with respect to block 64 about a rotation axis 42 (FIG. 2) that lies out of the plane of hinge 30. There is therefore a right-hand rotational axis 42 above the right-hand links 72 of FIG. 3 and a left-hand rotational axis 42 above the left-hand links 72 of FIG. 3. Additional rotational axes 42 above hinge 30 are formed by additional crescent-shaped features (e.g., crescent-shaped slots in friction transfer arms 74 and in gear plates 62).

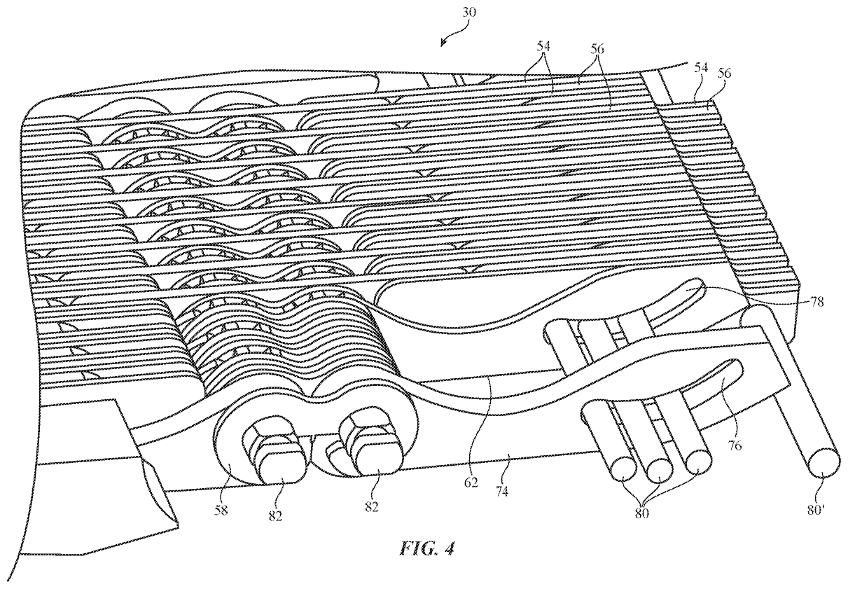

FIG. 4 is a perspective view of hinge 30 of FIG. 3 with some parts selectively removed so that crescent-shaped slots 76 in friction transfer arms 74 and crescent-shaped slots 78 in gear plates 62 are visible. Guide pins 80 and supplemental pin 80′ are coupled to mounting plate 50. Pin 80′ helps hold plates 54 and 56 rigidly in place relative to mounting block 50. Guide pins 80 slide within slots 76 and 78, thereby causing mounting block 50 to rotate relative to plates 62 and arms 74 about a second virtual pivot point. There is therefore an additional right-hand rotation axis 42 associated with this pivot point that is located above slots 76 and 78 on the right side of hinge 30 about which the right-hand plates 62 and arms 74 rotate relative to the right-hand block 50 and an additional left-hand rotation axis 42 located above slots 76 and 78 on the left side of hinge 30 about which the left-hand plates 62 and arms 74 rotate with respect to the left-hand block 50. These two additional rotation axes 42 are located above the plates and other structures (the “links”) forming respective rotating portions of hinge 30, as described in connection with axes 42 of FIG. 2.

Arms 74 are rigidly attached to shafts 82, so that shafts 82 rotate with arms 74. Friction clips 58 are attached to shafts 82 and receive shafts 82 to provide rotational friction to shafts 82. Clips 58 may, as an example, provide a first amount of friction (torque) to right-hand arms 74 when they are rotated clockwise and a second amount of friction (torque) to right-hand arms 74 when they are rotated counterclockwise. Similarly, the left-hand arms 74 may be provided with different amounts of friction depending on the direction of arm rotation (and therefore shaft rotation) relative to clips 58. With this arrangement, a first amount of resistance is provided when opening hinge 30 to unfold display 14 and a second amount of frictional resistance (e.g., a lower amount of resistance) is provided when closing hinge 30. This may help balance out torques generated by folding display 14.

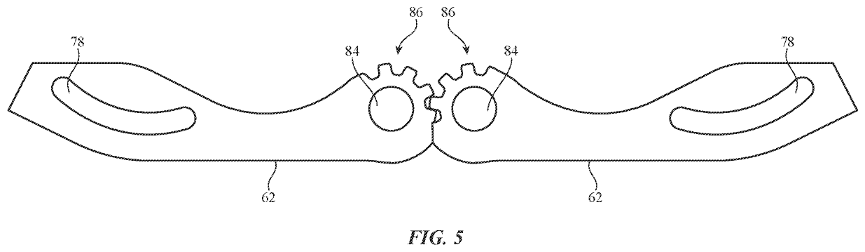

A pair of mating gear plates 62 is shown in FIG. 5. Gear plates 62 have openings 84 that receive shafts 82, so that plates 62 can rotate about shafts 82. Gear plates 62 have interlocking teeth 86. When one half of housing 12 is rotated about axis 28, the mating teeth of plates 62 cause the other half of housing 12 to rotate in synchronization. Each gear plate 62 also has a crescent-shaped slot 78 that receives guide pins 80 (FIG. 4).

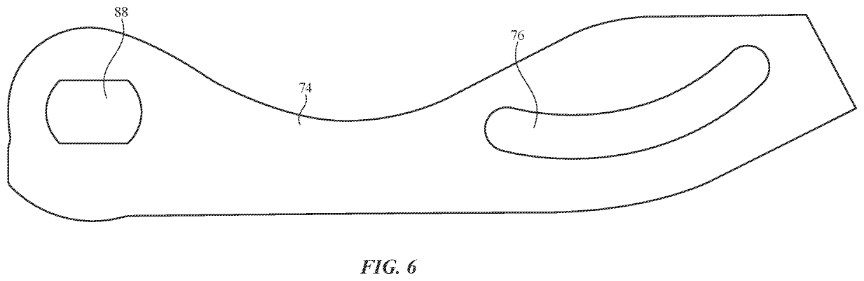

An illustrative friction transfer arm 74 is shown in FIG. 6. As shown in FIG. 6, arm 74 has a flat-sided opening such as opening 88 that rigidly receives shaft 82, so that shaft 82 rotates in unison with arm 74. Arm 74 also has a crescent-shaped slot 76 that receives guide pins 80 (FIG. 4).

To help protect the privacy of users, any personal user information that is gathered by sensors may be handled using best practices. These best practices including meeting or exceeding any privacy regulations that are applicable. Opt-in and opt-out options and/or other options may be provided that allow users to control usage of their personal data.

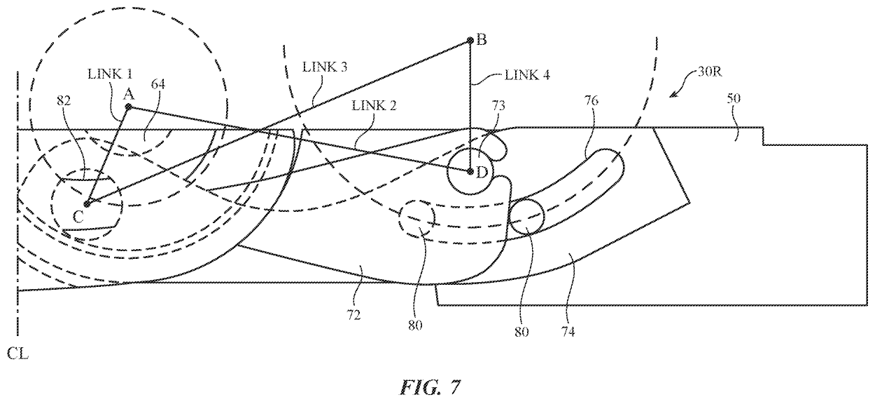

FIG. 7 is a side view of the half of hinge 30. Hinge 30 has symmetrical right and left halves. Right half 30R is shown in FIG. 7 as an example. Hinge 30 also has a symmetrical left half, which is joined with right half 30R along center line CL. During folding and unfolding operations, device 10 and display 14, which overlap centerline CL, fold and unfold about center line CL.

The diagram of FIG. 7 shows how the elements of each half of hinge 30 are used to form a 4-bar mechanism (sometimes referred to as a four-bar linkage or four-bar linkage hinge portion). Each four-bar linkage has four links: LINK1 (sometimes referred to as the ground link), LINK2, LINK3, and LINK4 (sometimes referred to as the housing link) and four pivot points A, B, C, and D.

One of the links (e.g., gear plates 62) in each four-bar linkage is geared so that each half of the hinge maintains rotational synchronization at pivot C with the other during folding and unfolding of device 10. As shown in FIG. 7, pivot point C is associated with rotation of gear plates 62 about shafts 82. Pivot point D is associated with rotation of crescent link 72 about pin 73. Two of the pivot points (A and B), which may sometimes be referred to as virtual pivot points or virtual pivots, lie out of the plane of the hinge to reduce stress on display 14, as described in connection with virtual pivot points 42 of FIG. 2. Pivot point A is associated with rotation of crescent block 64 relative to crescent link 72. During rotation about pivot point A, crescent-shaped ridge 70 of crescent link 72 slides within crescent-shaped groove 68 of crescent block 64. Pivot point B is associated with rotation of friction transfer arm 74 with respect to mounting block 50. During rotation about pivot point B, guide pins 80, which are attached to mounting block 50, slide within crescent-shaped slot 76 of arm 74.

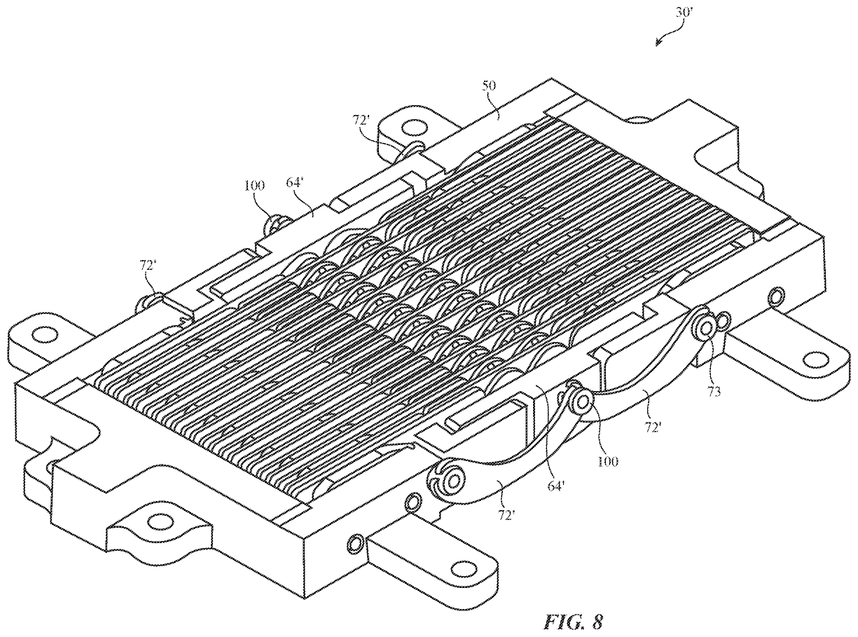

If desired, a single central pivot may replace the two centermost virtual pivots of hinge 30 of FIG. 3. An illustrative hinge with this type of pivot arrangement is shown in FIG. 8. As shown by hinge 30′ of FIG. 8, the pivots previously formed from the sliding interaction of crescent-shaped grooves 68 of crescent blocks 64 sliding within corresponding crescent-shaped ridges 70 on the inner ends of respective crescent links 72 in hinge 30 may be replaced with a single pivot formed by using pins 100 to couple links 72′ to blocks 64′ in hinge 30′ of FIG. 8. With this arrangement, pins 100 form a central pivot and that is surrounded on left and right by a pair of outer virtual pivot points (formed by the sliding movement of guide pins 80 within crescent-shaped slots 76 and 78 on the left and right sides of the central pivot). The pivot formed by pins 100 therefore lies between the virtual pivots formed by the sliding movement of pins 80 in slots 76 and 78.

The foregoing is merely illustrative and various modifications can be made to the described embodiments. The foregoing embodiments may be implemented individually or in any combination.

What is claimed is:

1. An electronic device, comprising:
a foldable housing;
a flexible display panel coupled to the foldable housing; and
a hinge with rotationally synchronized left- and right four-bar linkage portions that have virtual pivot points that lie outside of the hinge.

2. The electronic device defined in claim 1 wherein the hinge includes first and second shafts and a friction clip that supplies rotational friction to the first and second shafts.

3. The electronic device defined in claim 2 wherein the friction clip comprises an asymmetric friction clip configured to provide a first amount of rotational friction to the first shaft as the first shaft rotates clockwise relative to the asymmetric friction clip and to provide a second amount of friction that is different than the first amount of friction as the first shaft rotates counterclockwise relative to the asymmetric friction clip.

4. The electronic device defined in claim 3 wherein the hinge comprises:
a block with a crescent-shaped groove that is coupled to the first shaft; and
a crescent link having a crescent shaped ridge that slides within the crescent-shaped groove.

5. The electronic device defined in claim 4 wherein the block is configured to receive the first and second shafts.

6. The electronic device defined in claim 3 wherein the hinge comprises:
an arm with a crescent-shaped slot; and
a block coupled to a guide pin that slides within the crescent-shaped slot.

7. The electronic device defined in claim 6 wherein the arm is attached to the first shaft and is configured to rotate in unison with the first shaft.

8. The electronic device defined in claim 6 further comprising a gear plate with a crescent-shaped slot that receives the guide pin.

9. The electronic device defined in claim 3 wherein the asymmetric friction clip is configured to provide a third amount of rotational friction to the second shaft as the second shaft rotates clockwise relative to the asymmetric friction clip and to provide a fourth amount of friction that is different than the third amount of friction when the second shaft rotates counterclockwise relative to the asymmetric friction clip.

10. The electronic device defined in claim 2 wherein the hinge comprises a pair of gear plates with interlocking teeth configured to rotationally synchronize the left- and right four-bar linkage portions.

11. The electronic device defined in claim 10 wherein each gear plate has a crescent-shaped slot.

12. The electronic device defined in claim 1 wherein the virtual pivot points comprise first and second virtual pivot points, wherein the hinge comprises first and second plates with first and second respective crescent-shaped slots within which first and second respective guide pins slide respectively forming the first and second virtual pivot points and wherein the hinge has a central pivot located between the first and second virtual pivot points.

13. An electronic device, comprising:
a foldable housing;
a flexible display panel coupled to the foldable housing; and
a hinge having left- and right four-bar linkages, wherein the hinge has portions that rotate relative to each other about a rotation axis that lies outside of the hinge.

14. The electronic device defined in claim 13, wherein the hinge includes first and second gear plates having interlocking teeth, wherein the first and second gear plates are configured to synchronize rotational movement of the left four-bar linkage with the right four-bar linkage.

15. The electronic device defined in claim 14 wherein the hinge comprises:
an arm with a crescent-shaped slot; and
a block coupled to a guide pin that slides within the crescent-shaped slot.

16. The electronic device defined in claim 15 wherein the hinge includes first and second shafts and wherein the arm is attached to the first shaft and is configured to rotate in unison with the first shaft.

17. The electronic device defined in claim 16 wherein the first gear plate has a crescent-shaped slot that receives the guide pin.

18. The electronic device defined in claim 14 wherein the hinge comprises:
first and second shafts;
a block with a crescent-shaped groove that is coupled to the first shaft; and
a crescent link having a crescent shaped ridge that slides within the crescent-shaped groove.

19. The electronic device defined in claim 18 wherein the block is configured to receive the first and second shafts.

20. The electronic device defined in claim 13 further comprising:
plates with crescent shaped slots that form first and second virtual pivots; and
pins that form a central pivot between the first and second virtual pivots.

21. An electronic device, comprising:
a foldable housing;
a flexible display panel coupled to the foldable housing; and
a hinge having first and second four-bar linkage portions with virtual pivot points that lie outside of the hinge.

22. The electronic device defined in claim 21 wherein, the hinge comprises:
first and second gear plates having interlocking teeth that are configured to synchronize rotational movement of the first four-bar linkage portion with the second four-bar linkage portion;
a shaft that extends parallel to the bend axis; and
a friction clip that supplies rotational friction to the shaft.

23. The electronic device defined in claim 22 further comprising:
a crescent block with a crescent-shaped groove that is coupled to the shaft; and
a crescent link having a crescent shaped ridge that slides within the crescent-shaped groove.

24. The electronic device defined in claim 22 further comprising:
a friction transfer arm with a crescent-shaped slot; and
a mounting block coupled to a guide pin that slides within the crescent-shaped slot.

25. The electronic device defined in claim 24 wherein the first gear plate has a crescent-shaped slot in which the guide pin slides and wherein the first gear plate has a thickness of less than 4 mm.

26. The electronic device defined in claim 21 wherein the virtual pivot points include first and second virtual pivot points and wherein the hinge comprises:
first and second gear plates having interlocking teeth that are configured to synchronize rotational movement of the first four-bar linkage portion with the second four-bar linkage portion, wherein the first and second gear plates have respective first and second crescent-shaped slots that receive pins to form the first and second virtual pivot points and wherein the hinge comprises a central pivot between the first and second virtual pivot points.
